(19) United States
(12) Patent Application Publication
(10) Pub. No.: US 2026/0186041 A1
(43) Pub. Date: Jul. 2, 2026

(54) SYSTEM AND METHOD FOR DIAGNOSING PREMISES EQUIPMENT USING REACTIVE POWER CONTROLLER

(71) Applicant: Korea Electronics Technology Institute, Seongnam-si (KR)

(72) Inventors: Seung Hyeon PARK, Yongin-si (KR); Young Ho KIM, Incheon (KR); Ki Woong KWON, Seoul (KR)

(73) Assignee: Korea Electronics Technology Institute, Seongnam-si (KR)

(21) Appl. No.: 19/406,383

(22) Filed: Dec. 2, 2025

(30) Foreign Application Priority Data
Dec. 30, 2024 (KR) 10-2024-0200454

(51) Int. Cl. G01R 31/00

(52) U.S. Cl. CPC G01R 31/00

(57) ABSTRACT

Provided are a system and a method for diagnosing equipment in premises using reactive power controllers. An equipment diagnosis method according to an embodiment may include: applying reactive power to equipment while changing the reactive power; calculating a reactivity of the equipment according to the change in the reactive power; and predicting a degree of degradation of the equipment from the reactive power applied to the equipment and the calculated reactivity of the equipment. Accordingly, costs for establishing an equipment diagnosis system of an industrial low-voltage customer and costs required for installing and calibrating sensors required for the equipment diagnosis system may be reduced.

### CROSS-REFERENCE TO RELATED APPLICATION(S) AND CLAIM OF PRIORITY

This application is based on and claims priority under 35 U.S.C. § 119 to Korean Patent Application No. 10-2024-0200454, filed on Dec. 30, 2024, in the Korean Intellectual Property Office, the disclosure of which is herein incorporated by reference in its entirety.

### BACKGROUND

### Field

The disclosure relates to an equipment diagnosis technology, and more particularly, to a system and a method for diagnosing degradation and abnormality of equipment in premises of an industrial low-voltage customer.

### Description of Related Art

To diagnose equipment, it is necessary to collect operation data through various sensors. Motor equipment mostly configured for industrial low-voltage customers should have sensors attached thereto to collect data on vibrations, temperature, etc. However, vibration, temperature sensors often require periodic calibration, so that additional labor time and costs are expected for managing multiple pieces of equipment.

In addition, there is a need for a diagnosis technique suitable for corresponding equipment, in addition to installation/calibration of sensors, but in the case of a customer having various pieces of equipment, the cost for establishing a diagnosis system is bound to be burdensome.

### SUMMARY

The disclosure has been developed in order to solve the above-described problems, and an object of the disclosure is to provide, as a solution to reduce the cost required for establishing an equipment diagnosis system of an industrial low-voltage customer and the cost required for installing and calibrating sensors needed for this, a system and a method for diagnosing premises equipment, which are capable of controlling reactive power by using reactive power controllers already installed for management of power quality, and predicting a degree of degradation of equipment based on a reactivity of equipment changing according to adjustment of reactive power.

According to an embodiment of the disclosure to achieve the above-described object, an equipment diagnosis method may include: applying reactive power to equipment while changing the reactive power; calculating a reactivity of the equipment according to the change in the reactive power; and predicting a degree of degradation of the equipment from the reactive power applied to the equipment and the calculated reactivity of the equipment.

According to an embodiment, the equipment diagnosis method may further include: applying the reactive power to the equipment while changing the reactive power; acquiring power quality data of the equipment; calculating a reactivity of the equipment according to the change in the reactive power from the acquired power quality data; generating statistical data on the power quality data of the equipment according to the change in the reactive power; predicting a degree of degradation of the equipment, based on the acquired statistical data; matching the reactive power applied to the equipment and the calculated reactivity of the equipment with the predicted degree of degradation of the equipment, and accumulating results of matching; and generating an equipment degradation prediction model based on the accumulated results, and predicting may include predicting a degree of degradation of the equipment from the reactive power applied to the equipment and the calculated reactivity of the equipment by using the equipment degradation prediction model.

The Reactivity Of The Equipment May Be A Change In Power Factor of the equipment. The statistical data on the power quality data of the equipment may be the numbers of operation cycles at each power quality level of the equipment, and a duration of each operation cycle.

The operation cycle may be a period from when a power quality level of the equipment changes from a previous power quality level to when the power quality level changes to a next power quality level, the number of operation cycles at each power quality level may be the number of operation cycles counted for each power quality level, and the duration may be a time during which the operation cycle remains unchanged.

The degree of degradation of the equipment may have a positive correlation with a variance of the numbers of operation cycles at each power quality level of the equipment. The degree of degradation of the equipment may have a positive correlation with a variance of the durations of each operation cycle at each power quality level of the equipment.

Acquiring the power quality data of the equipment may include: collecting power quality data at a measurement point to which the equipment is connected; and extracting the power quality data of the equipment from the power quality data collected at the measurement point.

The power quality data may include at least one of voltage, current, active power, reactive power, phase, apparent power, power factor, load unbalance, voltage distortion.

According to another aspect of the disclosure, there is provided an equipment diagnosis system including: a communication unit communicatively connected with a reactive power controller; and a processor configured to control the reactive power controller to apply reactive power to equipment through the communication unit while changing the reactive power, to calculate a reactivity of the equipment according to the change in the reactive power, and to predict a degree of degradation of the equipment from the reactive power applied to the equipment and the calculated reactivity of the equipment.

According to still another aspect of the disclosure, there is provided a method for generating an equipment degradation prediction model, the method including: applying reactive power to equipment while changing the reactive power; acquiring power quality data of the equipment; calculating a reactivity of the equipment according to the change in the reactive power from the acquired power quality data; generating statistical data on the power quality data of the equipment according to the change in the reactive power; predicting a degree of degradation of the equipment, based on the acquired statistical data; matching the reactive power applied to the equipment and the calculated reactivity of the equipment with the predicted degree of degradation of the equipment, and accumulating results of matching; and generating an equipment degradation prediction model based on the accumulated results.

As described above, according to embodiments of the disclosure, by adjusting reactive power by using reactive power controllers already installed to manage power quality, and predicting a degree of degradation of equipment based on a reactivity of the equipment changing according to the adjustment of reactive power, costs for establishing an equipment diagnosis system of an industrial low-voltage customer and costs required for installing and calibrating sensors required for the equipment diagnosis system may be reduced.

According to embodiments of the disclosure, it is possible to take measures to degradation using electrical characteristics of equipment, and electricity bills of customers may be reduced, and safety accidents such power outages caused by short circuits and electrical fires caused by leakage current may be prevented.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating an example of a power system to which a premises equipment diagnosis method using reactive power controllers is applied;

FIG. 2 is a view illustrating types of power quality data;

FIG. 3 is a flowchart illustrating a premises equipment diagnosis method using reactive power controllers according to an embodiment of the disclosure;

FIG. 4 is a view illustrating cumulative data for predicting equipment degradation;

FIG. 5 is a view illustrating a configuration of an equipment diagnosis system.

### DETAILED DESCRIPTION

Hereinafter, the disclosure will be described in more detail with reference to the accompanying drawings.

Embodiments of the disclosure propose a premises equipment diagnosis system and method using reactive power controllers. The disclosure relates to a technology for adjusting reactive power by using reactive power controllers in premises of an industrial low-voltage customer, and for predicting a degree of degradation of equipment based on a reactivity of equipment changing according to the adjustment of reactive power.

Compared to related-art technologies of using sensors for measuring degradation data of equipment, a method and a system in embodiments of the disclosure may diagnose degradation and abnormality of equipment by sharing power quality data measured by reactive power controllers already installed to manage power quality in premises.

In particular, in embodiments of the disclosure, a degradation prediction model may be generated by analyzing proxy variables indirectly indicating degradation in a statistical method, rather than variables directly indicating degradation of equipment, and may be utilized for diagnosing.

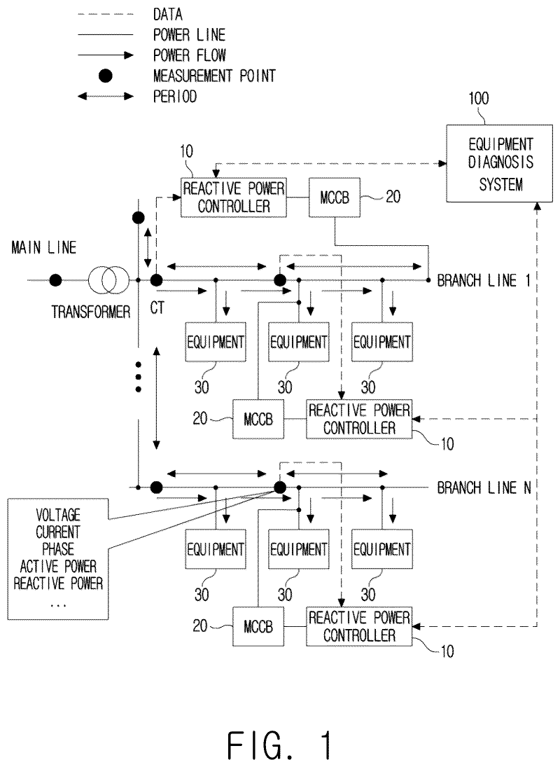

FIG. 1 is a view illustrating a power system to which an embodiment of the disclosure is applied. The power system to which an embodiment of the disclosure is applied may include reactive power controllers 10, molded case circuit breakers (MCCBs) 20, a plurality of pieces of equipment 30, and an equipment diagnosis system 100.

The reactive power controllers 10 are devices for measuring power quality data at measurement points (green) and adjusting reactive power in the system, and are connected to branch points to supply power to equipment 30 through the MCCBs 20.

The equipment diagnosis system 100 may collect power quality data measured by the reactive power controllers 10, may extract power quality data of equipment 30 connected to the measurement points, and may diagnose degradation and abnormality of the equipment 30 by using the extracted power quality data. The power quality data at measurement points may include power quality data of the equipment 30 connected to the measurement points, such that it is possible to extract power quality data of the equipment 30 connected to the measurement points from the power quality data of the measurement points by using a well-known data extraction algorithm and a clustering technique.

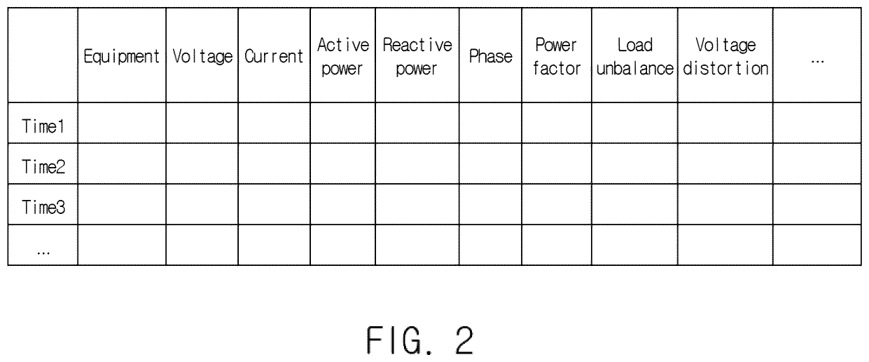

The power quality data may include voltages, currents, active power, reactive power, phases, and apparent power, power factor, load unbalance, voltage distortion, etc., may be added through calculation. FIG. 2 illustrates power quality data, and as shown in FIG. 2, data may be accumulated by time and equipment.

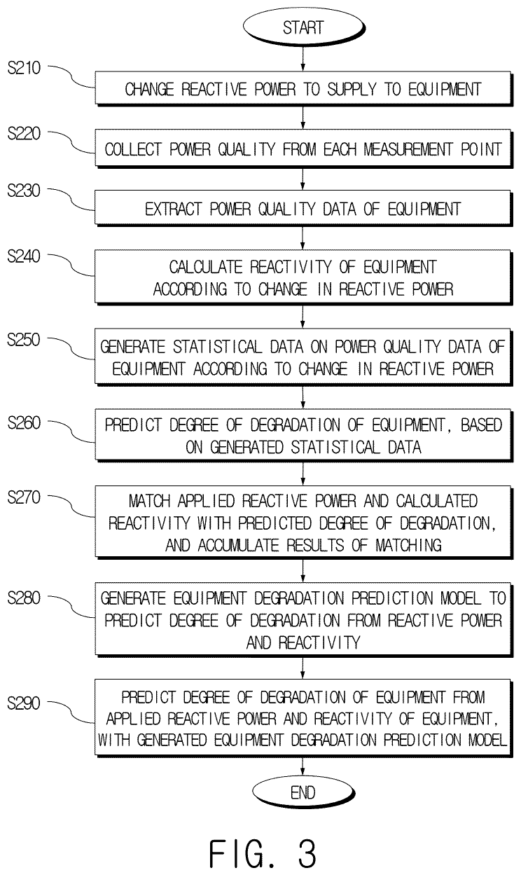

To diagnose the plurality of pieces of equipment 30, the equipment diagnosis system 100 may generate/update an equipment degradation prediction model based on power quality data of each piece of equipment 30, and may predict a degree of degradation of each piece of equipment 30 from the power quality data of each piece of equipment 30 by using the equipment degradation prediction model. This process will be described in detail hereinbelow with reference to FIG. 3.

FIG. 3 is a flowchart of a premises equipment diagnosis method using reactive power controllers according to an embodiment of the disclosure.

To diagnose degradation and abnormality of the plurality of pieces of equipment 30, the equipment diagnosis system 100 may control the reactive power controllers 100 to change reactive power to supply to the plurality of pieces of equipment 30 connected to the measurement points (S210).

The equipment diagnosis system 100 may collect power quality data at each measurement point through the reactive power controllers 100 (S220), and may extract power quality data of each piece of equipment from the power quality data collected at each measurement point (S230). The power quality data may include voltages, currents, active power, reactive power, phases, power factor, load unbalance, voltage distortion, etc. as shown in FIG. 2.

The equipment diagnosis system 100 may calculate a reactivity of each piece of equipment 30 to change in the reactive power from the power quality data of each piece of equipment 30 extracted at step S230 (S240). The reactivity of each piece of equipment 30 may be calculated based on change in the power factor of the equipment 30. However, other types of power quality data, for example, change in the load unbalance, change in the voltage distortion, or change in combined plurality of pieces of power quality data may be replaced.

The equipment diagnosis system 100 may generate statistical data on the power quality data of each piece of equipment 30 according to the change in the reactive power at step S210 (S240). The statistical data on the power quality data of each piece of equipment 30 may be the number of operation cycles at each reactive power level and a duration of each operation cycle of each piece of equipment 30.

The operation cycle refers to a period from when a reactive power level of equipment changes from a previous reactive power level to when the reactive power changes to a next reactive power level, and the number of operation cycles at each reactive power level is the number of operation cycles counted for each reactive power level. The duration of each operation cycle refers to a time during which the operation cycle remains unchanged, and is calculated in each operation cycle.

For example, when the equipment 30 is operated in sequence of “operating at reactive power level #1 for 30 minutes→changing to reactive power level #2 and operating for 50 minutes→changing to reactive power level #3 and operating for 40 minutes→changing back to reactive power level #2 and operating for 60 minutes”, the number of operation cycles at each reactive power level of the equipment 30, and a duration of each operation cycle at each reactive power level are as follows:
Reactive power level #1=>Number of operation cycles: 1, Duration: 30 minutes
Reactive power level #2=>Number of operation cycles: 2, Duration: 50 minutes, 60 minutes
Reactive power level #3=>Number of operation cycles: 1, Duration: 40 minutes.

The number of operation cycles at each reactive power level and the duration of each operation cycle at each reactive power level may tell how many times and how long the equipment 30 is operated at a corresponding reactive power level.

The equipment diagnosis system 100 may predict a degree of degradation of each piece of equipment 30, based on the statistical data acquired at step S250 (S260).

The degree of degradation of the equipment 30 may have a positive correlation with a variance of the numbers of operation cycles at each reactive power level of the equipment 30, and may have a positive correlation with a variance of the durations of each operation cycle at each reactive power level of the equipment 30. That is, as the variance of the numbers of operation cycles at each reactive power level of the equipment 30 is larger and the variance of the durations of each operation cycle at each reactive power levels of the equipment 30 is larger, the degree of degradation of the equipment 30 may be predicted to be higher. This is because as the degree of degradation is higher, the reactive power level of the equipment 30 changes more frequently, which causes the numbers of operation cycles at each reactive power level and the durations of each operation cycle to become uneven.

The reactive power level which is a basis for constructing the statistical data may be replaced with other types of power quality data, for example, an active power level, or a combination of power quality data, for example, a combination of voltage, current, active power, reactive power.

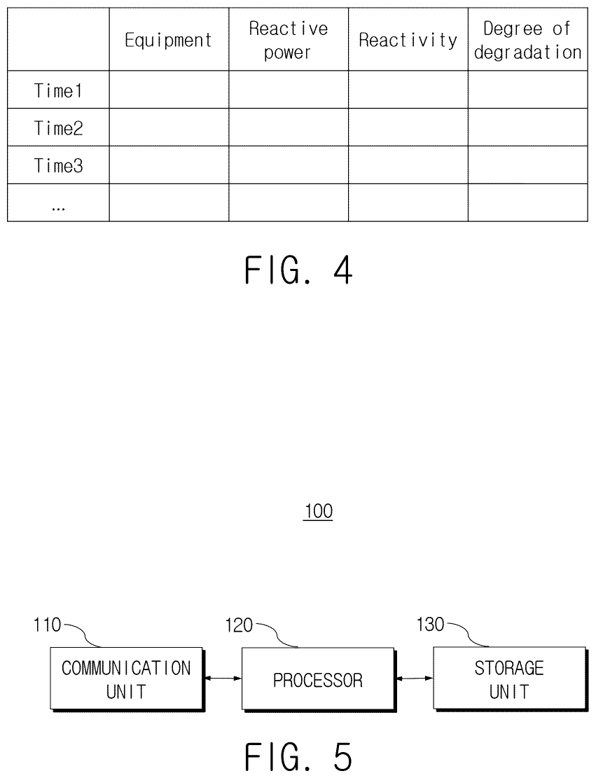

The equipment diagnosis system 100 may match the reactive power applied to the equipment 30 at step S210 and the reactivity of the equipment 30 calculated at step S240, with the degree of degradation of the equipment 30 precited at step 260, and may accumulate results of matching (S270). The data accumulated at step S270 is illustrated in FIG. 4.

When the data presented in FIG. 4 is accumulated according to change in the reactive power, the equipment degradation prediction model may be generated to be able to predict a degree of degradation from reactive power and reactivity by using the accumulated data (S280). In generating the equipment degradation prediction model, a K-Means clustering technique may be used. Furthermore, it is also possible to continuously update the equipment degradation prediction model while continuously accumulating the data presented in FIG. 4.

By using the equipment degradation prediction model generated through step S280, a degree of degradation of the equipment 30 may be predicted from reactive power applied to the equipment 30 and a reactivity of the equipment 30 in response thereto (S290).

In order to predict more accurately, reactive power may be applied to the equipment 30, more specifically, to the measurement point to which the equipment 30 is connected, while changing the reactive power, and reactivities of the equipment 30 may be calculated based on change in the reactive power, and a degree of degradation of the equipment 30 may be predicted by averaging the degrees of degradation predicted from the applied reactive power and the calculated reactivities of the equipment.

FIG. 5 is a view illustrating a detailed configuration of the equipment diagnosis system 100 shown in FIG. 1. The equipment diagnosis system 100 according to an embodiment may be implemented by a computing server which includes a communication unit 110, a processor 120, and a storage unit 130 as shown in FIG. 5.

The communication unit 110 may be a communication interface for connecting with an external network or an external device, and may receive power quality data measured at each point of the system from the reactive power controllers 10.

The processor 120 may generate/update an equipment degradation prediction model based on power quality data of each piece of equipment 30 according to the procedure shown in FIG. 3, and may predict a degree of degradation of each piece of equipment 30 from the power quality data of each piece of equipment 30.

The storage unit 130 may provide a storage space necessary for the processor 120 to function and operate.

Up to now, the premises equipment diagnosis system and method using reactive power controllers has been described in detail with reference to preferred embodiments.

In the above embodiments, by adjusting reactive power by using reactive power controllers already installed to manage power quality, and predicting a degree of degradation of equipment based on a reactivity of the equipment changing according to the adjustment of reactive power, costs for establishing an equipment diagnosis system of an industrial low-voltage customer and costs required for installing and calibrating sensors required for the equipment diagnosis system may be reduced.

Compared to related-art methods using sensors for checking only measured values, the method of the disclosure may use a kind of response characteristic to check a reactivity of each piece of equipment to reactive power by comparing changes in the reactive power supplied by the reactive power controllers. Interaction data equivalent to testing equipment removed from an operating process may be obtained.

The technical concept of the disclosure may be applied to a computer-readable recording medium which records a computer program for performing the functions of the apparatus and the method according to the present embodiments. In addition, the technical idea according to various embodiments of the disclosure may be implemented in the form of a computer readable code recorded on the computer-readable recording medium. The computer-readable recording medium may be any data storage device that can be read by a computer and can store data. For example, the computer-readable recording medium may be a read only memory (ROM), a random access memory (RAM), a CD-ROM, a magnetic tape, a floppy disk, an optical disk, a hard disk drive, or the like. A computer readable code or program that is stored in the computer readable recording medium may be transmitted via a network connected between computers.

In addition, while preferred embodiments of the present disclosure have been illustrated and described, the present disclosure is not limited to the above-described specific embodiments. Various changes can be made by a person skilled in the at without departing from the scope of the present disclosure claimed in claims, and also, changed embodiments should not be understood as being separate from the technical idea or prospect of the present disclosure.

What is claimed is:

1. An equipment diagnosis method comprising:
applying reactive power to equipment while changing the reactive power;
calculating a reactivity of the equipment according to the change in the reactive power; and
predicting a degree of degradation of the equipment from the reactive power applied to the equipment and the calculated reactivity of the equipment.

2. The equipment diagnosis method of claim 1, further comprising:
applying the reactive power to the equipment while changing the reactive power;
acquiring power quality data of the equipment;
calculating a reactivity of the equipment according to the change in the reactive power from the acquired power quality data;
generating statistical data on the power quality data of the equipment according to the change in the reactive power;
predicting a degree of degradation of the equipment, based on the acquired statistical data;
matching the reactive power applied to the equipment and the calculated reactivity of the equipment with the predicted degree of degradation of the equipment, and accumulating results of matching; and
generating an equipment degradation prediction model based on the accumulated results,
wherein predicting comprises predicting a degree of degradation of the equipment from the reactive power applied to the equipment and the calculated reactivity of the equipment by using the equipment degradation prediction model.

3. The equipment diagnosis method of claim 2, wherein the reactivity of the equipment is a change in power factor of the equipment.

4. The equipment diagnosis method of claim 2, wherein the statistical data on the power quality data of the equipment is the numbers of operation cycles at each power quality level of the equipment, and a duration of each operation cycle.

5. The equipment diagnosis method of claim 4, wherein the operation cycle is a period from when a power quality level of the equipment changes from a previous power quality level to when the power quality level changes to a next power quality level,
wherein the number of operation cycles at each power quality level is the number of operation cycles counted for each power quality level, and
wherein the duration is a time during which the operation cycle remains unchanged.

6. The equipment diagnosis method of claim 5, wherein the degree of degradation of the equipment has a positive correlation with a variance of the numbers of operation cycles at each power quality level of the equipment.

7. The equipment diagnosis method of claim 6, wherein the degree of degradation of the equipment has a positive correlation with a variance of the durations of each operation cycle at each power quality level of the equipment.

8. The equipment diagnosis method of claim 2, wherein acquiring the power quality data of the equipment comprises:
collecting power quality data at a measurement point to which the equipment is connected; and
extracting the power quality data of the equipment from the power quality data collected at the measurement point.

9. The equipment diagnosis method of claim 2, wherein the power quality data comprises at least one of voltage, current, active power, reactive power, phase, apparent power, power factor, load unbalance, voltage distortion.

10. An equipment diagnosis system comprising:
a communication unit communicatively connected with a reactive power controller; and
a processor configured to control the reactive power controller to apply reactive power to equipment through the communication unit while changing the reactive power, to calculate a reactivity of the equipment according to the change in the reactive power, and to predict a degree of degradation of the equipment from the reactive power applied to the equipment and the calculated reactivity of the equipment.

11. A method for generating an equipment degradation prediction model, the method comprising:
applying reactive power to equipment while changing the reactive power;
acquiring power quality data of the equipment;
calculating a reactivity of the equipment according to the change in the reactive power from the acquired power quality data;
generating statistical data on the power quality data of the equipment according to the change in the reactive power;
predicting a degree of degradation of the equipment, based on the acquired statistical data;
matching the reactive power applied to the equipment and the calculated reactivity of the equipment with the predicted degree of degradation of the equipment, and accumulating results of matching; and
generating an equipment degradation prediction model based on the accumulated results.
